(19) United States
(12) Patent Application Publication
(10) Pub. No.: US 2024/0088092 A1
(43) Pub. Date: Mar. 14, 2024

(54) SEMICONDUCTOR PACKAGE

(71) Applicant: Samsung Electronics Co., Ltd., Suwon-si (KR)

(72) Inventors: Jaekyung Yoo, Suwon-si (KR); Woohyeong Kim, Suwon-si (KR); Jinwoo Park, Suwon-si (KR); Jayeon Lee, Suwon-si (KR); Chungsun Lee, Suwon-si (KR)

(21) Appl. No.: 18/462,610

(22) Filed: Sep. 7, 2023

(30) Foreign Application Priority Data
Sep. 13, 2022 (KR) 10-2022-0114703
Apr. 14, 2023 (KR) 10-2023-0049326

(51) Int. Cl. H01L 25/065; H01L 23/31; H01L 23/498; H01L 23/538

(52) U.S. Cl. CPC H01L 25/0652; H01L 23/3128; H01L 23/49811; H01L 23/5383; H01L 24/16; H01L 2224/16227

(57) ABSTRACT

A semiconductor package includes a redistribution substrate having a first surface including first and a second regions and a second surface opposite to the first surface, and including a first redistribution layer, first and second semiconductor chips positioned in a first direction on the first region the redistribution substrate, each of the first and second semiconductor chips being electrically connected to the first redistribution layer, a first molding layer on the first region on the first and second semiconductor chips, a redistribution structure on the first molding layer and including a second redistribution layer, conductive posts on the first region and electrically connecting the first redistribution layer to the second redistribution layer, third and fourth semiconductor chips positioned in a second direction, intersecting the first direction, and each electrically connected to the second redistribution layer, and a second molding layer on the second region the redistribution substrate and on the third and fourth semiconductor chips.

### CROSS-REFERENCE TO RELATED APPLICATION(S)

This application claims benefit of priority to Korean Patent Application Nos. 10-2022-0114703 filed on Sep. 13, 2022, and 10-2023-0049326 filed on Apr. 14, 2023, in the Korean Intellectual Property Office, the disclosures of which are incorporated herein by reference in its entirety.

### BACKGROUND

The present inventive concept relates to a semiconductor package including a plurality of semiconductor chips.

With the development of the electronics industry, demand for high functionality, high speed, and miniaturization of electronic components has increased. According to this trend, packages have been manufactured by mounting a plurality of semiconductor chips on a single interposer or package substrate. Due to differences in coefficients of thermal expansion (CTE) between individual components constituting semiconductor packages, a warpage phenomenon in which semiconductor packages are bent may occur, and in particular, semiconductor packages employing a plurality of semiconductor chips are prone to severe warpage.

### SUMMARY

An aspect of the present inventive concept is to provide a semiconductor package capable of controlling warpage.

According to an aspect of the present inventive concept, a semiconductor package includes: a redistribution substrate including a first surface and a second surface opposite to the first surface, the first surface having a first region and a second region extending around at least a portion of the first region, the redistribution substrate including a plurality of first insulating layers and a plurality of first redistribution layers that are sequentially stacked and electrically connected to each other; a first lower semiconductor chip and a second lower semiconductor chip positioned in a first direction on the first region of the first surface of the redistribution substrate and each having a plurality of first contact pads electrically connected to the plurality of first redistribution layers, respectively; a plurality of conductive posts around the first and second lower semiconductor chips on the first region of the first surface of the redistribution substrate; a first molding layer on the first region of the first surface of the redistribution substrate and on the plurality of conductive posts and the first and second lower semiconductor chips; a redistribution structure on the first molding layer and including a plurality of second insulating layers and a plurality of second redistribution layers that are sequentially stacked and electrically connected to the plurality of first redistribution layers by the plurality of conductive posts; a first upper semiconductor chip and a second upper semiconductor chip positioned in a second direction, intersecting the first direction, and overlapping a region between the first and second lower semiconductor chips on the redistribution structure and each having a plurality of second contact pads electrically connected to the plurality of second redistribution layers; and a second molding layer on the second region of the first surface of the redistribution substrate and on the redistribution structure and the first and second upper semiconductor chips.

According to another aspect of the present inventive concept, a semiconductor package includes: a redistribution substrate including a first surface and a second surface opposite to the first surface, the first surface having a first region and a second region extending around at least a portion of the first region, the redistribution substrate including a plurality of first insulating layers and a plurality of first redistribution layers that are sequentially stacked and electrically connected to each other; a plurality of lower semiconductor chips on the first region of the first surface of the redistribution substrate and each electrically connected to the plurality of first redistribution layers, respectively, spaces between the plurality of lower semiconductor chips including a space extending from one side of the redistribution substrate to an opposite side of the redistribution substrate; a first molding layer on the first region of the first surface of the redistribution substrate and on the plurality of lower semiconductor chips; a redistribution structure on the first molding layer and including a plurality of second insulating layers and a plurality of second redistribution layers that are sequentially stacked and electrically connected to each other; a plurality of conductive posts on the first region of the first surface of the redistribution substrate and electrically connecting the plurality of first redistribution layers to the plurality of second redistribution layers; a plurality of upper semiconductor chips overlapping the space extending from one side of the redistribution substrate to an opposite side of the redistribution substrate, on the redistribution structure and each electrically connected to the plurality of second redistribution layers, respectively; and a second molding layer on the second region of the first surface of the redistribution substrate and on the redistribution structure and the plurality of upper semiconductor chips.

According to another aspect of the present inventive concept, a semiconductor package includes: a redistribution substrate having a first surface and a second surface opposite to the first surface, the first surface including a first region and a second region extending around at least a portion of the first region, and including a first redistribution layer; first and second semiconductor chips positioned in a first direction on the first region of the first surface of the redistribution substrate and each electrically connected to the first redistribution layer; a first molding layer on the first region of the first surface of the redistribution substrate and on the first and second semiconductor chips; a redistribution structure on the first molding layer and including a second redistribution layer; a plurality of conductive posts on the first region of the first surface of the redistribution substrate and electrically connecting the first redistribution layer to the second redistribution layer; third and fourth semiconductor chips positioned in a second direction, intersecting the first direction, to overlap a region between the first and second semiconductor chips on the redistribution structure, and each electrically connected to the second redistribution layer; and a second molding layer on the second region of the first surface of the redistribution substrate and on the redistribution structure and the third and fourth semiconductor chips.

### BRIEF DESCRIPTION OF DRAWINGS

The above and other aspects, features, and advantages of the present inventive concept will be more clearly understood from the following detailed description, taken in conjunction with the accompanying drawings, in which:

FIGS. 1 and 2 are a cross-sectional side view and a top plan view, respectively, of a semiconductor package according to an embodiment of the present inventive concept;

FIG. 3 is a schematic diagram illustrating warpage behavior of a lower structure of a semiconductor package employed in an embodiment of the present inventive concept;

FIG. 4 illustrates an arrangement of signal pads of semiconductor chips employed in the semiconductor package illustrated in FIG. 2;

FIGS. 5 and 6 are a side cross-sectional view and a top plan view, respectively, of a semiconductor package according to an embodiment of the present inventive concept;

FIG. 7 is a top plan view illustrating a semiconductor package according to an embodiment;

FIGS. 8A and 8B are side cross-sectional views of the semiconductor package illustrated in FIG. 7, taken along lines I3-I3′ and II-II, respectively; and

FIGS. 9A to 9F are cross-sectional views illustrating major processes of a method of manufacturing a semiconductor package according to an embodiment of the present inventive concept.

### DETAILED DESCRIPTION

Hereinafter, various embodiments of the present inventive concept will be described with reference to the accompanying drawings.

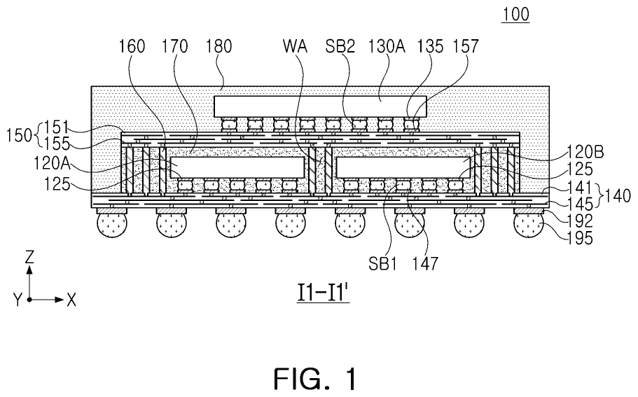

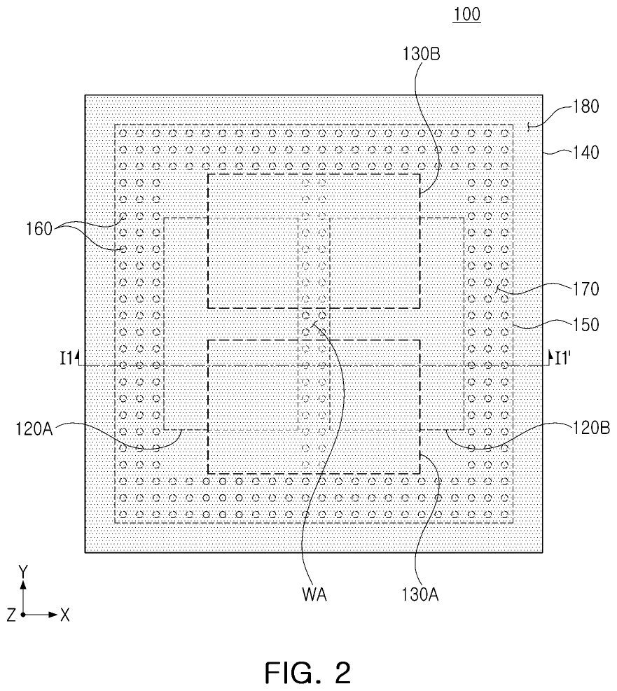

FIGS. 1 and 2 are a cross-sectional side view and a top plan view, respectively, of a semiconductor package according to an embodiment of the present inventive concept. Here, FIG. 1 may be understood as a side cross-sectional view of the semiconductor package of FIG. 2, taken along line I1-I1′.

Referring to FIGS. 1 and 2, a semiconductor package 100 according to the present embodiment has a two-level structure in which a plurality of semiconductor chips are positioned, and includes a redistribution substrate 140 having a first surface (or an upper surface) including a first region and a second region extending around at least a portion of (e.g., surrounding) the first region and a second surface (or a lower surface) located opposite to the first surface.

A first level structure of the semiconductor package 100 includes a first lower semiconductor chip 120A and a second lower semiconductor chip 120B in the first region of the first surface of the redistribution substrate 140, a plurality of conductive posts 160 around the first and second lower semiconductor chips 120A and 120B in the first region of the first surface of the redistribution substrate 140, and a first molding layer 170 on the first region of the first surface of the redistribution substrate 140 and on the plurality of conductive posts 160 and the first and second lower semiconductor chips 120A and 120B.

In addition, a second level structure of the semiconductor package 100 may include a redistribution structure 150 on the first molding layer 170, a first upper semiconductor chip 130A and a second upper semiconductor chip 130B, which are on the redistribution structure 150, and a second molding layer 180 on the second region of the first surface of the redistribution substrate 140 and on the redistribution structure 150 and the first and second upper semiconductor chips 130A and 130B.

The redistribution substrate 140 includes a plurality of first redistribution layers 145 and a plurality of first insulating layers 141 that are sequentially stacked and connected to each other. The first redistribution layer 145 may include a redistribution pattern on the first insulating layer 141 and a redistribution via passing through the first insulating layer 141 and connecting adjacent redistribution patterns. Although the redistribution substrate 140 employed in the present embodiment is illustrated as including three first redistribution layers 145, in other embodiments, the redistribution substrate 140 may be implemented to include one or two layers or more layers. Although the plurality of first insulating layer 141 are provided, a layer boundary may not be apparent depending on a material and process of each first insulating layers 141.

Similar to the redistribution substrate, the redistribution structure 150 also includes a plurality of second redistribution layers 155 and a plurality of second insulating layers 151 that are sequentially stacked and connected to each other. The second redistribution layer 155 may include redistribution patterns on the second insulating layer 151 and a redistribution via passing through the second insulating layer 151 and connecting adjacent redistribution patterns. The redistribution structure 150 employed in the present embodiment may be provided in a multilayer structure. For example, the first and second redistribution layers 145 and 155 may include a conductive material, such as copper (Cu), aluminum (Al), silver (Ag), tin (Sn), gold (Au), nickel (Ni), lead (Pb), titanium (Ti), or alloys thereof. In some embodiments, the first and second redistribution layers 145 and 155 may include a copper (Cu) plating layer.

The first and second lower semiconductor chips 120A and 120B each have a plurality of first contact pads 125 electrically connected to the plurality of first redistribution layers 145. A plurality of first bonding pads 147 connected to the first redistribution layers 145 may be on the first surface of the redistribution substrate 140, and the plurality of first contact pads 125 may be connected to the plurality of first bonding pads 147 by first conductive bumps SB1. In some embodiments, an underfill (not shown) on sidewalls of the first conductive bump SB1 may be provided between the redistribution substrate 140 and each of the first and second lower semiconductor chips 120A and 120B.

Similar to the first and second lower semiconductor chips 120A and 120B, the first and second upper semiconductor chips 130A and 130B may also be on the redistribution structure 150. The first and second upper semiconductor chips 130A and 130B each have a plurality of second contact pads 135 electrically connected to the plurality of second redistribution layers 155. A plurality of second bonding pads 157 connected to the second redistribution layers 155 are on the redistribution structure 150, and the plurality of second contact pads 135 may be respectively connected to the plurality of second bonding pads 157 by second conductive bumps SB2. In some embodiments, an underfill (not shown) on sidewalls of the second conductive bump SB2 may be provided between the redistribution structure 150 and each of the first and second upper semiconductor chips 130A and 130B.

The first insulating layer 141 and the second insulating layer 151 may include an insulating resin. For example, the first insulating layer 141 and the second insulating layer 151 may include epoxy, prepreg, or Ajinomoto Build-up Film (ABF) resin. In some embodiments, the first and second insulating layers 141 and 151 may use a photosensitive insulating material, such as photo-imageable dielectric (PID) resin. Although not limited thereto, as the semiconductor package 100 is miniaturized, the redistribution substrate 140 may have a thickness of 100 μm or less. The redistribution structure 150 may also have a thickness similar to that of the redistribution substrate 140 and may have a thickness of 100 μm or less.

The redistribution structure 150 may have an area smaller than that of the redistribution substrate 140. The redistribution structure 150 may have an area corresponding to the first region of the redistribution substrate 140. In the present embodiment, the first region may be defined as a region in which the first molding layer 170 is formed. In the present embodiment, the first molding layer 170 may have side surfaces that are flat and coplanar with side surfaces of the redistribution structure 150. Similarly, the second molding layer 180 may have side surfaces that are flat and coplanar with side surfaces of the redistribution substrate 140.

The first and second lower semiconductor chips 120A and 120B are side by side in a first direction (an X-direction) on the redistribution substrate 140. In the present embodiment, each of the first and second lower semiconductor chips 120A and 120B may have a rectangular body. A planar shape of the first and second lower semiconductor chips 120A and 120B may be a rectangle having a pair of longer sides and a pair of shorter sides. The first and second lower semiconductor chips 120A and 120B may be configured such that longer sides thereof face each other. A space WA between the first and second lower semiconductor chips 120A and 120B extends between opposing sides of the redistribution substrate 140 in the second direction (a Y-direction). That is, the space WA extends from one side of the redistribution substrate 140 to an opposite side of the redistribution substrate 140. This space WA may be a region where warpage is more likely to occur (e.g., a warpage occurrence point).

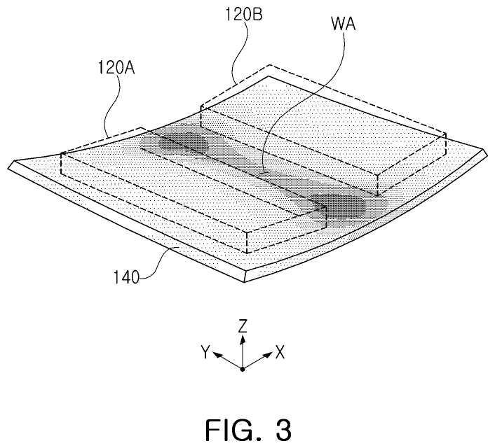

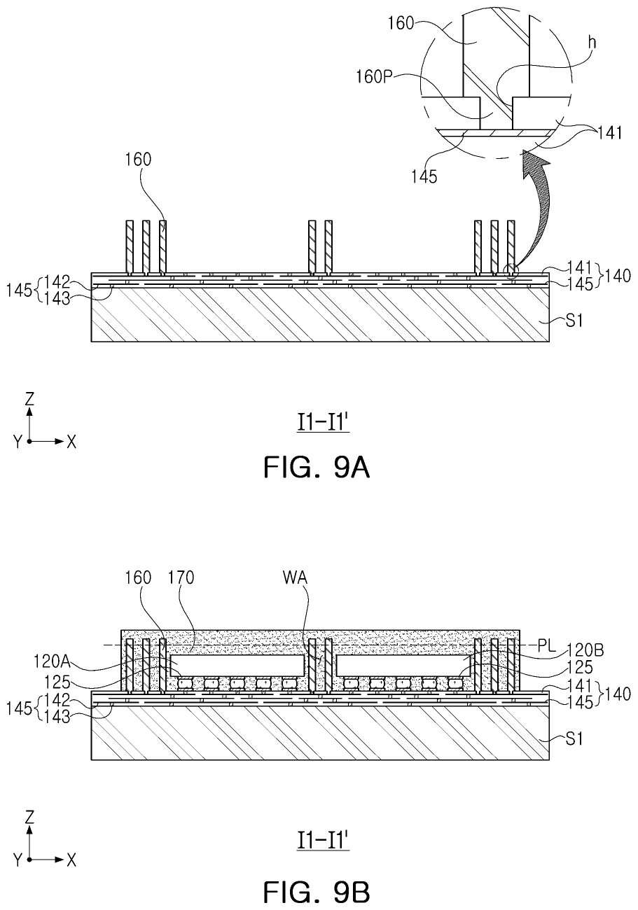

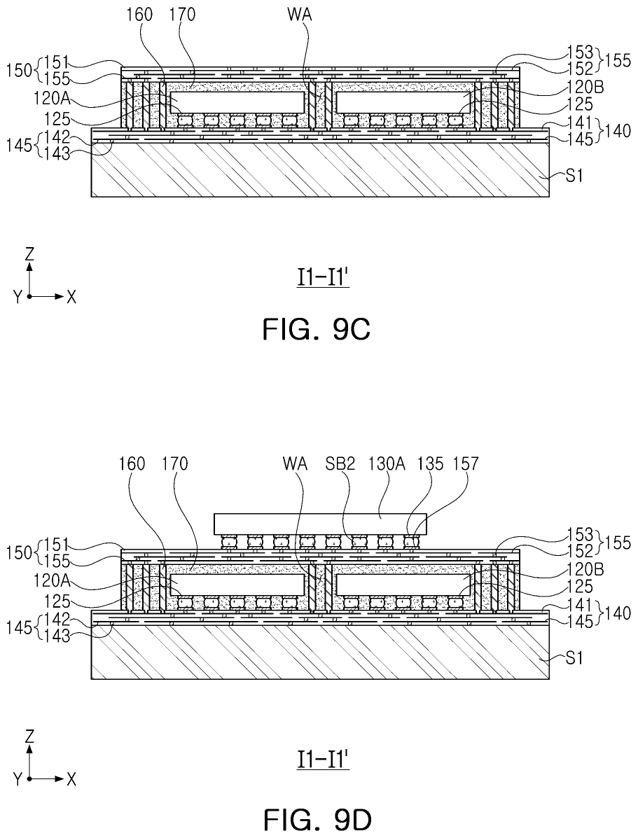

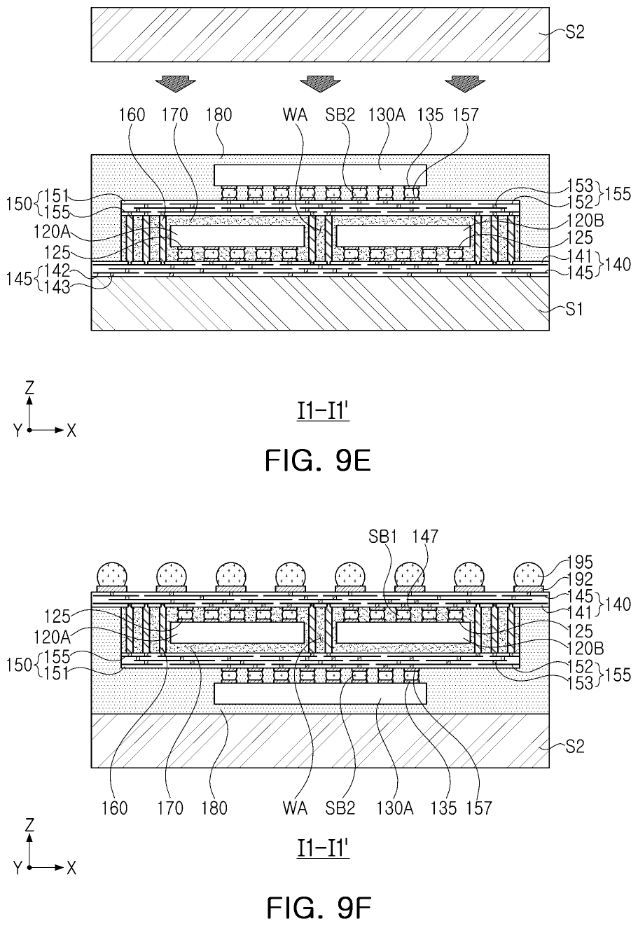

As illustrated in FIG. 3, a portion overlapping the space WA in a vertical direction (a Z-direction) is not covered by the first and second lower semiconductor chips 120A and 120B having high modulus, and warpage may occur severely in a case in which only structures (e.g., the redistribution substrate 140, the redistribution structure 150, and the first and second molding layers 170 and 180) having low rigidity are provided (large stress occurs in the dark portion in FIG. 3). During a manufacturing process of the semiconductor package, especially, after the formation of the second molding layer 180, warpage may occur seriously to make bonding (e.g., bonding of a second support substrate S2 (refer to FIG. 9E)) in a subsequent process difficult. In particular, when some of the plurality of conductive posts 160 are between the first and second lower semiconductor chips 120A and 120B as in the present embodiment, some of the conductive posts may be damaged by warpage.

In the present embodiment, by adjusting the arrangement of the first and second upper semiconductor chips 130A and 130B located on the redistribution structure 150, warpage caused by the space WA may be significantly alleviated.

Specifically, referring to FIG. 2, the first and second upper semiconductor chips 130A and 130B may be positioned in the second direction (the Y-direction), intersecting the first direction which is the arrangement direction of the first and second lower semiconductor chips 120A and 120B on the redistribution structure 150, and may overlap the open region WA between the first and second lower semiconductor chips 120A and 120B.

In this manner, structures located in the space WA between the first and second lower semiconductor chips 120A and 120B, which are vulnerable to warpage, may be reinforced using the relatively rigid first and second upper semiconductor chips 130A and 130B, thereby significantly alleviating the overall warpage problem.

The first and second upper semiconductor chips 130A and 130B employed in the present embodiment may have a body having a rectangular structure similar to the first and second lower semiconductor chips 120A and 120B. A planar shape of the first and second upper semiconductor chips 130A and 130B may be a rectangle having a pair of longer sides and a pair of shorter sides. The first and second upper semiconductor chips 130A and 130B may be configured such that longer sides thereof face each other.

In the present embodiment, the first and second lower semiconductor chips 120A and 120B and the first and second upper semiconductor chips 130A and 130B may be the same type of semiconductor chips.

The semiconductor chips 120A, 120B, 130A, and 130B employed in the present embodiment may include a semiconductor substrate, a plurality of active/passive devices (e.g., transistors) on an active surface of the semiconductor substrate, and the first and second contact pads 125 and 135 connected thereto. For example, the semiconductor substrate may include a single element semiconductor substrate, such as silicon or germanium, or a compound semiconductor substrate, such as silicon carbide (SiC), gallium arsenide (GaAs), indium arsenide (InAs), and indium phosphide (InP).

The semiconductor chips 120A, 120B, 130A, and 130B may include, for example, memory chips, such as a volatile memory (e.g., DRAM), a non-volatile memory (e.g., ROM), a flash memory, or logic chips, such as a microprocessor, a microcontroller, an analog-to-digital converter (ADC), an application-specific integrated circuit (ASIC). In the present embodiment, the first and second lower semiconductor chips 120A and 120B and the first and second upper semiconductor chips 130A and 130B may be memory chips.

The conductive posts 160 on the redistribution substrate 140 may electrically connect the plurality of first redistribution layers 145 and the plurality of second redistribution layers 155. The first and second lower semiconductor chips 120A and 120B may be electrically connected to the first and second upper semiconductor chips 130A and 130B through the first and second redistribution layers 145 and 155 and the conductive posts 160.

The semiconductor package 100 according to the present embodiment may further include an underbump metallurgy (UBM) layer 192 and an external connection conductor 195.

The UBM layer 192 may be formed to be connected to the lowermost first redistribution layer 145. For example, the UBM layer 192 may be formed through a plating process, but is not limited thereto. The external connection conductor 195 serves to physically and/or electrically connect the semiconductor package 100 to an external device, such as a main board of an electronic device. The external connection conductor 195 may include a low melting point metal, such as tin (Sn)-aluminum (Al)-copper (Cu) or tin-silver, or a copper pillar.

In the present embodiment, warpage of the semiconductor package 100 may be significantly alleviated by adjusting the arrangement of the semiconductor chips (in particular, the arrangement of the first and second upper semiconductor chips 130A and 130B). When the first and second lower semiconductor chips 120A and 120B and the first and second upper semiconductor chips 130A and 130B include the same type of semiconductor chips, the method for alleviating warpage according to the present embodiment provides may be expressed as an arrangement of signal pads rather than an arrangement of chips themselves.

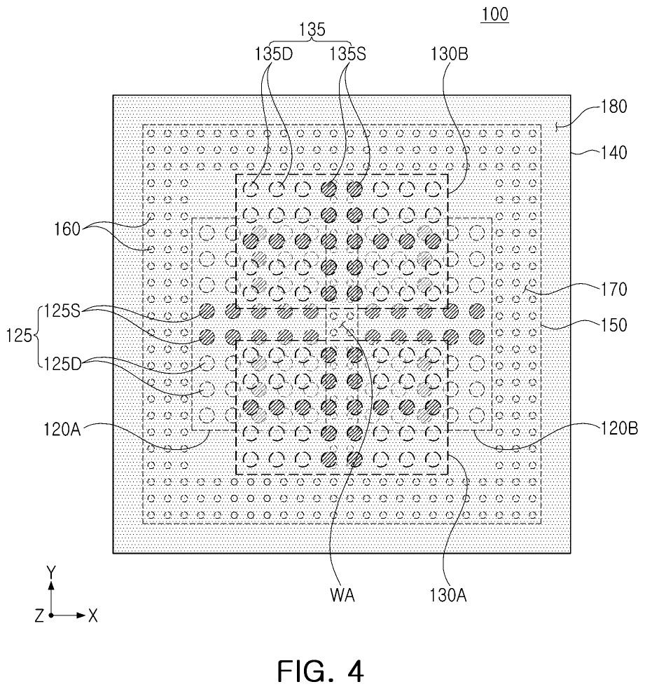

FIG. 4 illustrates an arrangement of signal pads of semiconductor chips employed in the semiconductor package illustrated in FIG. 2. The plane illustrated in FIG. 4 corresponds to the plane illustrated in FIG. 2, representing the arrangement of the first contact pads 125 of the first and second lower semiconductor chips 120A and 120B and the arrangement of the second contact pads 135 of the first and second upper semiconductor chips 130A and 130B.

Referring to FIG. 4, the first and second lower semiconductor chips 120A and 120B and the first and second upper semiconductor chips 130A and 130B may be the same type of semiconductor chips, and the first and second contact pads 125 and 135 may have the same arrangement. The first and second contact pads 125 and 135 may include first and second signal pads 125S and 135S for transmitting signals and first and second dummy pads 125D and 135D for stable support, respectively. In the present embodiment, the first and second signal pads 125S and 135S of each of the semiconductor chips 120A, 120B, 130A, and 130B are illustrated substantially in a cross shape. At least some of the first signal pads 125S may be configured not to overlap the second signal pads 135S in the vertical direction (the Z-direction). It is be understood that the non-overlapping arrangement of the first and second lower semiconductor chips 120A and 120B and the first and second upper semiconductor chips 130A and 130B results from cross-arrangement of the first and second lower semiconductor chips 120A and 120B and the first and second upper semiconductor chips 130A and 130B.

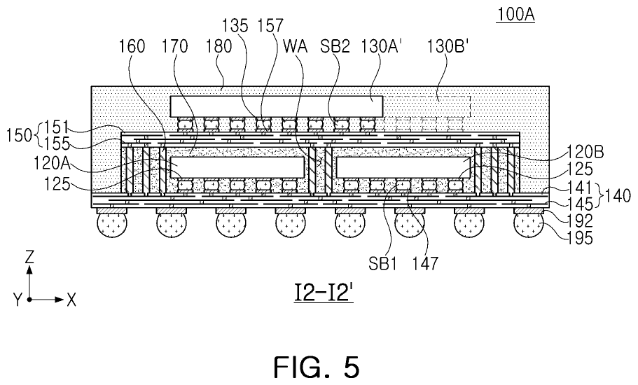

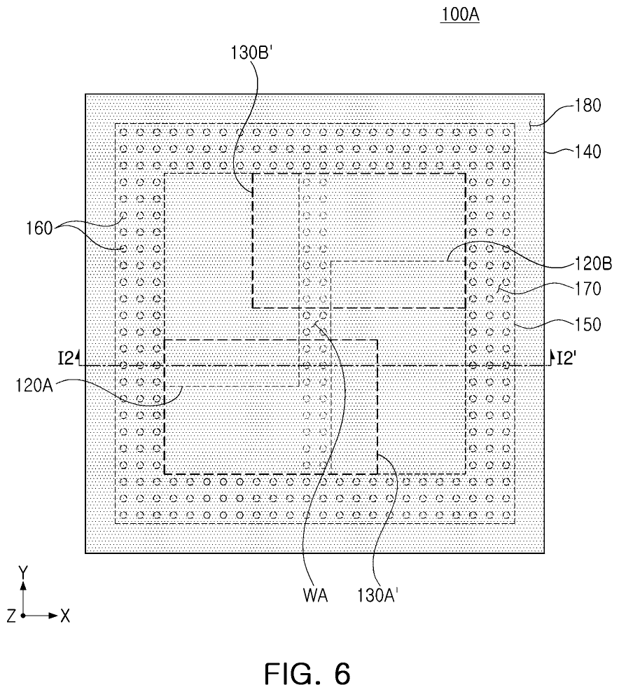

FIGS. 5 and 6 are a side cross-sectional view and a top plan view, respectively, of a semiconductor package according to an embodiment of the present inventive concept. Here, FIG. 5 may be understood as a side cross-sectional view of the semiconductor package of FIG. 6, taken along line I2-I2′.

Referring to FIGS. 5 and 6, a semiconductor package 100A according to the present embodiment may be understood as having a structure similar to that of the semiconductor package 100 illustrated in FIGS. 1 to 4, except that the first and second lower semiconductor chips 120A and 120B and the first and second upper semiconductor chips 130A and 130B are not side by side with each other. Accordingly, the description of the semiconductor package 100 illustrated in FIGS. 1 to 4 may be combined with the description of the present embodiment unless otherwise stated.

The first and second lower semiconductor chips 120A and 120B and the first and second upper semiconductor chips 130A and 130B may be the same type of semiconductor chips. As illustrated in FIG. 6, in plan view, the first and second lower semiconductor chips 120A and 120B and the first and second upper semiconductor chips 130A and 130B may have a rectangular shape having two longer sides and two shorter sides, respectively.

Similar to the previous embodiment, the first and second upper semiconductor chips 130A and 130B may be positioned in the second direction (the Y-direction), intersecting the first direction (the X-direction), to overlap the region WA between the first and second lower semiconductor chips 120A and 120B on the redistribution structure 150. With such an arrangement of the first and second upper semiconductor chips 130A and 130B, the occurrence of warpage due to the region WA between the first and second lower semiconductor chips 120A and 120B may be suppressed.

The first and second lower semiconductor chips 120A and 120B may be configured such that the longer sides thereof face each other and are offset from each other in the second direction (the Y-direction). That is, the first and second lower semiconductor chips 120A and 120B may be configured such that side surfaces related to the shorter sides thereof are not located on the same line (e.g., the same line extending in the first direction). Similarly, the first and second upper semiconductor chips 130A and 130B may also be configured such that the longer sides thereof face each other and are offset from each other in the first direction (the X-direction. As such, when the same type of chips having the same size are configured, the first and second upper semiconductor chips 130A and 130B may be positioned in 180° rotational symmetry with the first and second lower semiconductor chips 120A and 120B.

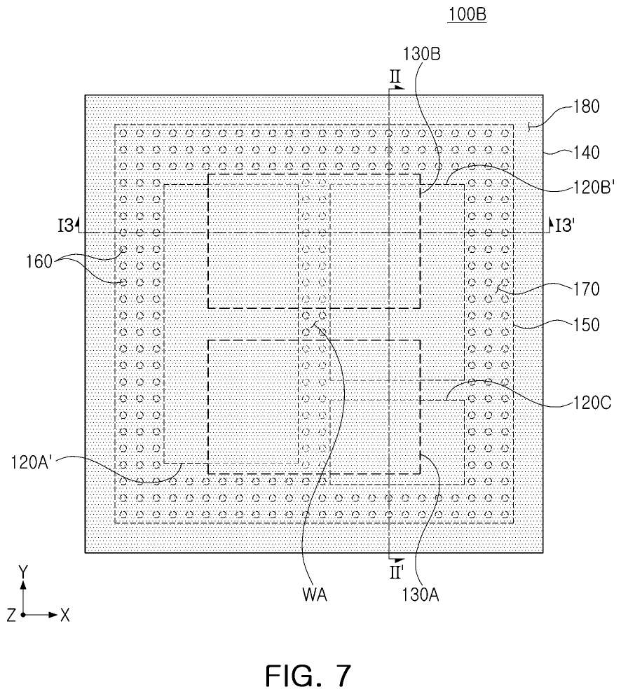

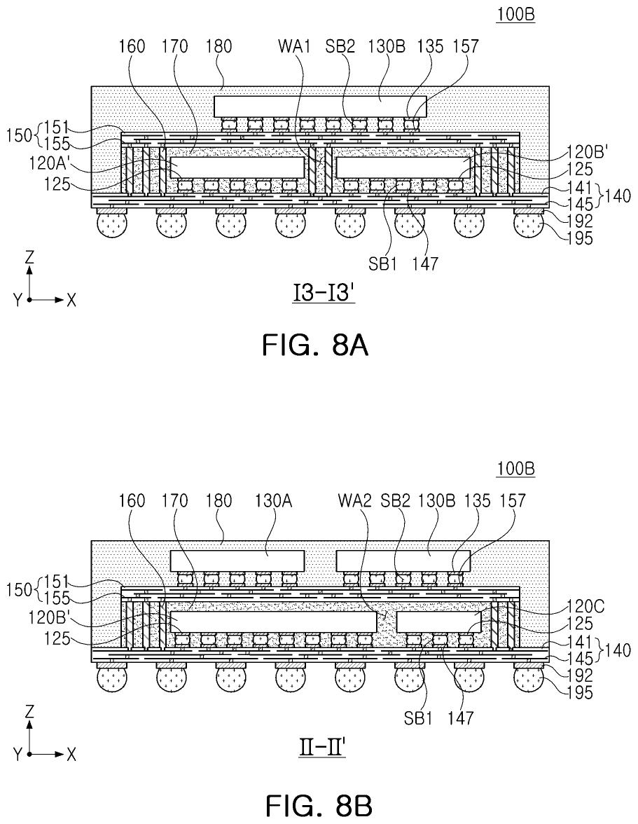

FIG. 7 is a top plan view illustrating a semiconductor package according to an embodiment, and FIGS. 8A and 8B are side cross-sectional views of the semiconductor package illustrated in FIG. 7, taken along lines I3-I3′ and II-II, respectively.

Referring to FIGS. 7, 8A, and 8B, a semiconductor package 100B according to the present embodiment may be understood as having a structure similar to that of the semiconductor package 100 illustrated in FIGS. 1 to 4, except that the lower semiconductor chip located in the first molding layer 170 includes three semiconductor chips 120A′, 120B′, and 120C, and the three semiconductor chips 120A′, 120B′, and 120C are different types (or sizes) of semiconductor chips (or sizes). Accordingly, the description of the semiconductor package 100 illustrated in FIGS. 1 to 4 may be combined with the description of the present embodiment unless otherwise stated.

The lower semiconductor chips employed in the present embodiment may include a first lower semiconductor chip 120A′ having a first area and second and third lower semiconductor chips 120B′ and 120C having an area smaller than the first area. Additionally, the second and third lower semiconductor chips 120B′ and 120C may have second and third areas different from each other. The first to third lower semiconductor chips 120A′, 120B′, and 120C employed in the present embodiment are illustrated to have a structure having a rectangular plane, but are not limited thereto, and some of the lower semiconductor chips may have a square structure.

The second and third lower semiconductor chips 120B′ and 120C may be configured along one side (e.g., a longer side) of the first lower semiconductor chip 120A′. The space WA between the first lower semiconductor chip 120A′ and the second and third lower semiconductor chips 120B′ and 120C may be a space WA extending toward (e.g., in the Y-direction) both sides of the redistribution substrate 140 facing each other. The first and second upper semiconductor chips 130A and 130B may be positioned side by side in the second direction (the Y-direction) to overlap the space WA on the redistribution structure. In the present embodiment, the first upper semiconductor chip 130A may additionally be positioned on or to cover at least a portion of a space between the second and third lower semiconductor chips 120B′ and 120C. For example, the first upper semiconductor chip 130A may extend over a space between the second and third lower semiconductor chips 120B′ and 120C. The space between the second and third lower semiconductor chips 120B′ and 120C may be a weak point for warpage, which may be less than that of the space WA though, and thus, the first upper semiconductor chip 130A may be appropriately positioned to alleviate the warpage problem. In the present embodiment, the upper semiconductor chips in the second molding layer 180 are illustrated as two, but may include three or more semiconductor chips.

FIGS. 9A to 9F are cross-sectional views of major processes of a method of manufacturing a semiconductor package according to an embodiment of the present inventive concept. A manufacturing process according to the present embodiment may be understood as a manufacturing process of the semiconductor package 100 illustrated in FIGS. 1 and 2.

Referring to FIG. 9A, the redistribution substrate 140 is formed, and conductive posts 160 are formed on the redistribution substrate 140.

In the present embodiment, the process of forming the redistribution substrate 140 and the conductive posts 160 may be performed on a first support substrate S1. The redistribution substrate 140 may be formed by repeatedly performing a process of forming the first insulating layer 141 and forming the first redistribution layer 145 on the first insulating layer 141. For example, the first insulating layer 141 may be formed of a photosensitive insulating resin, an opening may be formed in the first insulating layer 141 using a photolithography process, and the first redistribution layer 145 having a via (a portion filling the opening) passing through the first insulating layer 141 may then be formed using a plating process.

Subsequently, the conductive posts 160 connected to the uppermost first redistribution layer 145 may be formed on the redistribution substrate 140. In the present embodiment, the conductive posts 160 may be formed around a region including the lower semiconductor chips (130A and 130B of FIG. 9B). The conductive posts 160 employed in the present embodiment may be provided as a power/signal path connecting the first redistribution layer 145 of the redistribution substrate 140 to the second redistribution layer 155 of the redistribution structure 150 to be formed in a subsequent process (refer to FIG. 9C). For example, an opening h may be formed in the uppermost first insulating layer 141 so that a region of the uppermost first redistribution layer 145 is exposed, and the conductive posts 160 may be formed from the exposed region by using a plating process. The conductive posts 160 may be formed to have a sufficient height. For example, the conductive posts 160 may be formed to have a height greater than at least a top surface of the first lower semiconductor chip 120A.

Next, referring to FIG. 9B, the first and second lower semiconductor chips 120A and 120B are on the redistribution substrate 140 and a first molding layer 170 is formed.

During the process of arranging the chips, the first bonding pads 147 connected to the first redistribution layer 145 may be formed in the chip mounting region of the redistribution substrate 140, and the contact pads 125 of the first and second lower semiconductor chips 120A and 120B may be connected to the first bonding pads 147 using the first conductive bumps SB1.

The first molding layer 170 is formed on a portion of the redistribution substrate 140 to cover the first and second lower semiconductor chips 120A and 120B and the conductive posts 160. The first molding layer 170 may include an insulating resin, such as epoxy molding compound (EMC). Subsequently, a process of planarizing the first molding layer 170 up to a “PL” line is performed so that upper ends of the conductive posts 160 are exposed. As a result, the first molding layer 170 may have a substantially flat upper surface with the upper ends of the conductive posts 160, and the exposed upper ends of the conductive posts 160 may be electrically connected to the second redistribution layer 155 to be formed in a subsequent process (refer to FIG. 9C).

Next, referring to FIG. 9C, after the first molding layer 170 is polished, the redistribution structure 150 is formed on the first molding layer 170.

In the process of forming the redistribution structure 150, a process of forming the second redistribution layer similar to that of the redistribution substrate 140 is performed on the first molding layer 170. The second redistribution layer 155 may be formed to be connected to the exposed upper ends of the conductive posts 160. Accordingly, the conductive posts 160 may interconnect the first redistribution layer 145 of the redistribution substrate 140 and the second redistribution layer 155 of the redistribution structure 150 to form a single circuit.

The redistribution structure 150 may be formed by repeatedly performing processes of forming the second insulating layer 151 and forming the second redistribution layer 155 on the second insulating layer 151. For example, the second insulating layer 151 may be formed of a photosensitive insulating resin, an opening may be formed in the second insulating layer 151 using a photolithography process, and then the second redistribution layer 155 having a via (a portion filling the opening) passing through the second insulating layer 151 may be formed using a plating process.

The second redistribution layer 155 of the redistribution structure 150 formed in this process may be appropriately modified and designed in consideration of the arrangement of the first and second upper semiconductor chips described above with reference to FIGS. 1 and 2.

Subsequently, referring to FIG. 9D, the first and second upper semiconductor chips 130A and 130B are on the redistribution structure 150.

In the process of arranging the chips, the second bonding pads 157 connected to the second redistribution layer 155 may be formed on the redistribution structure 150, and the second contact pads 135 of the first and second upper semiconductor chips 130A and 130B may be connected to the second bonding pads 157 using the second conductive bumps SB2. As described above, the first and second upper semiconductor chips 130A and 130B may be positioned in the second direction (the Y-direction), intersecting the first direction, to overlap the space WA between the first and second lower semiconductor chips 120A and 120B on the redistribution structure 150. As such, when the second molding layer 180 is formed using the relatively rigid first and second upper semiconductor chips 130A and 130B, the structures located in the space WA between the first and second lower semiconductor chips 120A and 120B vulnerable to warpage may be reinforced, thereby significantly alleviating the occurrence of warpage on the whole.

Next, referring to FIG. 9E, the second molding layer 180 is formed on the redistribution substrate 140 to cover the redistribution structure 150 and the first molding layer 170, as well as the first and second upper semiconductor chips 130A and 130B.

The second molding layer 180 may be formed on (e.g., to cover) the entire area of the redistribution substrate. In a process of cutting into individual packages in a subsequent process, the second molding layer may have side surfaces that are flat and coplanar with side surfaces of the redistribution substrate.

The second molding layer 180 may be formed of an insulating resin, such as EMC, similarly to the first molding layer, but is not limited thereto, and the second molding layer may be formed of an insulating material different from that of the first molding layer 170. When the second molding layer is formed of other materials, warpage may be alleviated by varying the coefficient of thermal expansion. Meanwhile, even though the second molding layer 180 is formed of the same material as that of the first molding layer 170, since the second molding layer is formed by a different process, the second molding layer 180 may have an interface visually distinguishable from the first molding layer 170.

Next, referring to FIG. 9F, after bonding the second molding layer 180 on the second support substrate S2, the first support substrate S1 is separated from the redistribution substrate 140, and the UBM layer 192 and external connection conductors 195 are formed on the second surface of the redistribution substrate 140. The UBM layer 192 may be formed to be connected to the lowermost first redistribution layer 145. For example, the UBM layer 192 may be formed through a plating process. For example, the external connection conductor 195 may include a low melting point metal, such as tin (Sn)-aluminum (Al)-copper (Cu) or tin-silver, or a copper pillar.

According to the embodiment described above, deformation due to warpage may be alleviated by arranging the upper semiconductor chips to extend across or to cover the region between the lower semiconductor chips.

While embodiments have been illustrated and described above, it will be apparent to those skilled in the art that modifications and variations could be made without departing from the scope of the present inventive concept as defined by the appended claims.

What is claimed is:

1. A semiconductor package comprising:
a redistribution substrate including a first surface and a second surface opposite to the first surface, the first surface having a first region and a second region extending around at least a portion of the first region, the redistribution substrate including a plurality of first insulating layers and a plurality of first redistribution layers that are sequentially stacked and electrically connected to each other;
a first lower semiconductor chip and a second lower semiconductor chip positioned in a first direction on the first region of the first surface of the redistribution substrate, each of the first and second lower semiconductor chips having a plurality of first contact pads electrically connected to the plurality of first redistribution layers;
a plurality of conductive posts positioned around the first and second lower semiconductor chips on the first region of the first surface of the redistribution substrate;
a first molding layer on the first region of the first surface of the redistribution substrate and on the plurality of conductive posts and the first and second lower semiconductor chips;
a redistribution structure on the first molding layer and including a plurality of second insulating layers and a plurality of second redistribution layers that are sequentially stacked and electrically connected to the plurality of first redistribution layers by the plurality of conductive posts;
a first upper semiconductor chip and a second upper semiconductor chip positioned in a second direction, intersecting the first direction, and overlapping a region between the first and second lower semiconductor chips on the redistribution structure, each of the first and second upper semiconductor chips having a plurality of second contact pads electrically connected to the plurality of second redistribution layers; and
a second molding layer on the second region of the first surface of the redistribution substrate and on the redistribution structure and the first and second upper semiconductor chips.

2. The semiconductor package of claim 1, wherein the first and second lower semiconductor chips and the first and second upper semiconductor chips are a same type of semiconductor chips.

3. The semiconductor package of claim 2, wherein the first and second lower semiconductor chips and the first and second upper semiconductor chips each have a rectangular plane.

4. The semiconductor package of claim 3, wherein the first and second lower semiconductor chips are configured such that longer sides thereof face each other, and the first and second upper semiconductor chips are configured such that longer sides thereof face each other.

5. The semiconductor package of claim 4, wherein the first and second lower semiconductor chips are configured such that the longer sides thereof are configured to be offset from each other in the second direction.

6. The semiconductor package of claim 4, wherein the first and second upper semiconductor chips are configured such that the facing longer sides thereof are configured to be offset from each other in the first direction.

7. The semiconductor package of claim 2, wherein
the plurality of first contact pads include first signal pads, the plurality of second contact pads include second signal pads, and
at least one of the first signal pads do not overlap the second signal pads in a vertical direction.

8. The semiconductor package of claim 1, wherein the redistribution substrate has a thickness of 100 μm or less.

9. The semiconductor package of claim 1, wherein the redistribution structure has a thickness of 100 μm or less.

10. The semiconductor package of claim 1, wherein each of the plurality of first and second insulating layers includes a photosensitive insulating layer.

11. The semiconductor package of claim 1, wherein the first molding layer has side surfaces that are respectively coplanar with side surfaces of the redistribution structure.

12. The semiconductor package of claim 1, wherein the second molding layer has side surfaces that are respectively coplanar with side surfaces of the redistribution substrate.

13. The semiconductor package of claim 1, wherein the plurality of conductive posts include conductive posts positioned between the first and second lower semiconductor chips.

14. A semiconductor package comprising:
a redistribution substrate including a first surface and a second surface opposite to the first surface, the first surface having a first region and a second region extending around at least a portion of the first region, the redistribution substrate including a plurality of first insulating layers and a plurality of first redistribution layers that are sequentially stacked and electrically connected to each other;
a plurality of lower semiconductor chips on the first region of the first surface of the redistribution substrate, each of the plurality of lower semiconductor chips electrically connected to the plurality of first redistribution layers, wherein spaces between the plurality of lower semiconductor chips include a space extending from one side of the redistribution substrate to an opposite side of the redistribution substrate;
a first molding layer on the first region of the first surface of the redistribution substrate and on the plurality of lower semiconductor chips;
a redistribution structure on the first molding layer and including a plurality of second insulating layers and a plurality of second redistribution layers that are sequentially stacked and electrically connected to each other;
a plurality of conductive posts on the first region of the first surface of the redistribution substrate and electrically connecting the plurality of first redistribution layers to the plurality of second redistribution layers;
a plurality of upper semiconductor chips overlapping the space extending from one side of the redistribution substrate to an opposite side of the redistribution substrate, on the redistribution structure and each electrically connected to the plurality of second redistribution layers; and
a second molding layer on the second region of the first surface of the redistribution substrate and on the redistribution structure and the plurality of upper semiconductor chips.

15. The semiconductor package of claim 14, wherein the plurality of lower semiconductor chips include a first lower semiconductor chip having a first area and second and third lower semiconductor chips having an area less than the first area.

16. The semiconductor package of claim 15, wherein the second and third lower semiconductor chips are along one side of the first lower semiconductor chip, and a space is between the first lower semiconductor chip and the second and third lower semiconductor chips.

17. The semiconductor package of claim 16, wherein the plurality of upper semiconductor chips include an upper semiconductor chip on at least a portion of the space between the second and third lower semiconductor chips.

18. The semiconductor package of claim 14, wherein
each of the plurality of first and second insulating layers includes a photosensitive insulating resin layer, and
each of the redistribution substrate and the redistribution structure has a thickness of 100 μm or less.

19. A semiconductor package comprising:
a redistribution substrate having a first surface and a second surface opposite to the first surface, the first surface including a first region and a second region on the first region and, and including a first redistribution layer;
first and second semiconductor chips positioned in a first direction on the first region of the first surface of the redistribution substrate, each of the first and second semiconductor chips being electrically connected to the first redistribution layer;
a first molding layer on the first region of the first surface of the redistribution substrate and on the first and second semiconductor chips;
a redistribution structure on the first molding layer and including a second redistribution layer;
a plurality of conductive posts on the first region of the first surface of the redistribution substrate and electrically connecting the first redistribution layer to the second redistribution layer;
third and fourth semiconductor chips positioned in a second direction, intersecting the first direction, to overlap a region between the first and second semiconductor chips on the redistribution structure, and each electrically connected to the second redistribution layer; and
a second molding layer on the second region of the first surface of the redistribution substrate and on the redistribution structure and the third and fourth semiconductor chips.

20. The semiconductor package of claim 19, wherein the first to fourth semiconductor chips include a same type of memory chips having a rectangular planar shape.
